(19) United States
(12) Patent Application Publication
(10) Pub. No.: US 2024/0120017 A1
(43) Pub. Date: Apr. 11, 2024

(54) RAM AND SHORT-CIRCUIT DETECTION SYSTEM

(71) Applicant: ROHM Co., LTD., Kyoto (JP)

(72) Inventors: Kosuke Ijigawa, Kyoto (JP); Kazuhisa Ukai, Kyoto (JP)

(21) Appl. No.: 18/474,518

(22) Filed: Sep. 26, 2023

(30) Foreign Application Priority Data
Oct. 5, 2022 (JP) 2022-160829

(51) Int. Cl. G11C 29/50; G01R 31/52; G11C 7/12

(52) U.S. Cl. CPC G11C 29/50008; G01R 31/52; G11C 7/12

(57) ABSTRACT

Provided is a RAM including a first read bit line, a first write bit line, a second read bit line, a second write bit line, a charge circuit configured to charge one of the first and second read bit lines and the first and second write bit lines at a time of short-circuit detection, and a discharge circuit configured to discharge the other of the first and second read bit lines and the first and second write bit lines at the time of the short-circuit detection.

### CROSS REFERENCE TO RELATED APPLICATIONS

This application claims priority benefit of Japanese Patent Application No. JP 2022-160829 filed in the Japan Patent Office on Oct. 5, 2022. Each of the above-referenced applications is hereby incorporated herein by reference in its entirety.

### BACKGROUND

A technology disclosed in the present specification relates to a random access memory (RAN) and a short-circuit detection system having the RAM.

A RAM disclosed in PCT Patent Publication No. WO2007/018043 (paragraph 0002) can execute data reading from a first memory cell and data writing to a second memory cell simultaneously or almost simultaneously. Such a RAM can execute processing of data at high speed.

### BRIEF DESCRIPTION OF THE DRAWINGS

FIG. 1 is a schematic diagram illustrating the major part of a 2-port RAM according to a comparative example;

FIG. 2 is a schematic diagram illustrating the major part of the 2-port RAM according to the comparative example in a case in which there is a short-circuit between a second write bit line and a second read bit line;

FIG. 3 is a schematic diagram illustrating the major part of the 2-port RAM according to the comparative example in the case in which there is the short-circuit between the second write bit line and the second read bit line;

FIG. 4 is a timing chart illustrating the timings of write operation and read operation;

FIG. 5 is a timing chart illustrating the timings of write operation and read operation;

FIG. 6 is a schematic diagram illustrating the major part of the 2-port RAM according to the comparative example at the time of standby;

FIG. 7 is a schematic diagram illustrating the major part of 2-port RAMs according to first and second embodiments;

FIG. 8 is a schematic diagram illustrating the major part of the 2-port RAM according to the first embodiment at the time of standby in a case in which there is a short-circuit between a second write bit line and a second read bit line;

FIG. 9 is a schematic diagram of a short-circuit detection system; and

FIG. 10 is a schematic diagram illustrating the major part of the 2-port RAM according to the second embodiment at the time of a test mode in a case in which there is a short-circuit between the second write bit line and the second read bit line.

### DETAILED DESCRIPTION

In the present specification, a metal oxide semiconductor (MOS) field effect transistor refers to a field effect transistor in which the structure of a gate is composed of at least three layers of a “layer composed of an electrical conductor or a semiconductor such as polysilicon with a small resistance value,” an “insulating layer,” and a “P-type, N-type, or intrinsic semiconductor layer.” That is, the structure of the gate of the MOS field effect transistor is not limited to a three-layer structure of metal, an oxide, and a semiconductor.

### 2-Port RAM (Comparative Example)

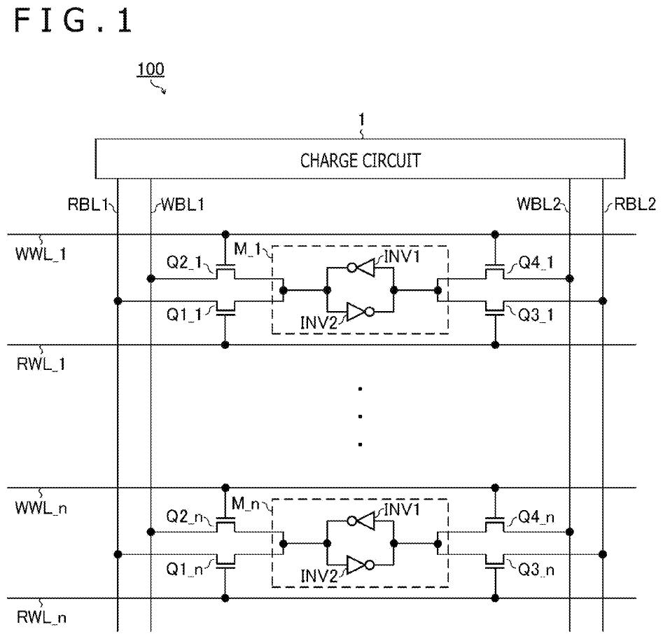

FIG. 1 is a schematic diagram illustrating the major part of a 2-port RAM according to a comparative example (=a general configuration example contrasted with an embodiment to be described later).

A 2-port RAM 100 according to the comparative example has a first read bit line RBL1, a first write bit line WBL1, a second read bit line RBL2, and a second write bit line WBL2.

The 2-port RAM 100 according to the comparative example has a port exclusively for input (not illustrated) and a port exclusively for output (not illustrated). The first read bit line RBL1 is used for reading out data from a memory cell selected at the time of read operation.

The first write bit line WBL1 is used for writing data to a memory cell selected at the time of write operation.

The second read bit line RBL2 is used for reading out data from a memory cell selected at the time of read operation.

The second write bit line WBL2 is used for writing data to a memory cell selected at the time of write operation.

The 2-port RAM 100 according to the comparative example includes n memory cells M_1 to M_n, n read word lines RWL_1 to RWL_n, n write word lines WWL_1 to WWL_n, n first switches Q1_1 to Q1_n, n second switches Q2_1 to Q2_n, n third switches Q3_1 to Q3_n, n fourth switches Q4_1 to Q4_n, and a charge circuit 1.

The read word line RWL_1 is used for selecting the memory cell M_1 at the time of read operation. The other read word lines RWL_2 to RWL_n are also similarly used for selecting the memory cells M_2 to M_n, respectively, at the time of read operation.

The write word line WWL_1 is used for selecting the memory cell M_1 at the time of write operation. The other write word lines WWL_2 to WWL_n are also similarly used for selecting the memory cells M_2 to M_n, respectively, at the time of write operation.

It is desirable that the first switches Q1_1 to Q1_n, the second switches Q2_1 to Q2_n, the third switches Q3_1 to Q3_n, and the fourth switches Q4_1 to Q4_n be N-channel MOS field effect transistors in terms of size reduction.

The first switch Q1_1 is disposed between the memory cell M_1 and the first read bit line RBL1. The on-state and the off-state of the first switch Q1_1 are switched according to the voltage level of the read word line RWL_1. This applies also to the other first switches Q1_2 to Q1_n.

The second switch Q2_1 is disposed between the memory cell M_1 and the first write bit line WBL1. The on-state and the off-state of the second switch Q2_1 are switched according to the voltage level of the write word line WWL_1. This applies also to the other second switches Q2_2 to Q2_n.

The third switch Q3_1 is disposed between the memory cell M_1 and the second read bit line RBL2. The on-state and the off-state of the third switch Q3_1 are switched according to the voltage level of the read word line RWL_1. This applies also to the other third switches Q3_2 to Q3_n.

The fourth switch Q4_1 is disposed between the memory cell M_1 and the second write bit line WBL2. The on-state and the off-state of the fourth switch Q4_1 are switched according to the voltage level of the write word line WWL_1. This applies also to the other fourth switches Q4_2 to Q4_n.

The charge circuit 1 is a circuit configured to charge some or all of the first read bit line RBL1, the first write bit line WBL1, the second read bit line RBL2, and the second write bit line WBL2.

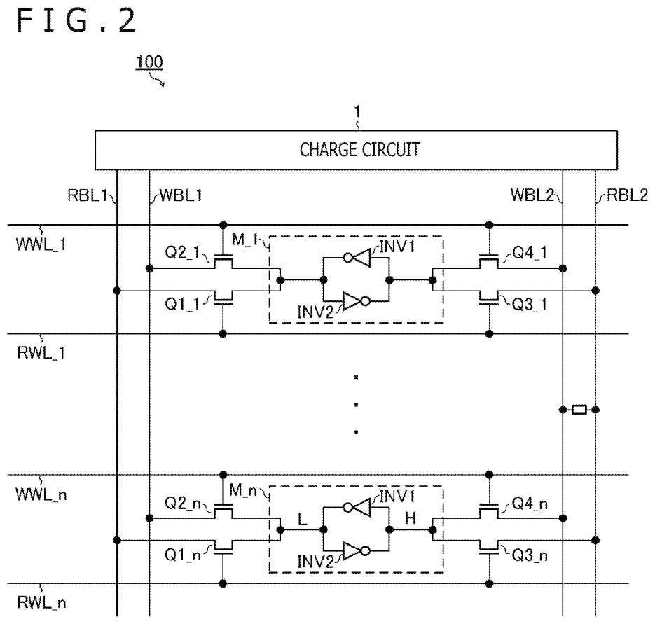

Here, a consideration will be made with regard to a case in which, as illustrated in FIG. 2, data “0” is written in the memory cell M_n and the second write bit line WBL2 and the second read bit line RBL2 are short-circuited. When data “0” is written in a memory cell, the output of an inverter INV1 in the memory cell is at the LOW level while the output of an inverter INV2 in the memory cell is at the HIGH level. Conversely, when data “1” is written in a memory cell, the output of the inverter INV1 in the memory cell is at the HIGH level while the output of the inverter INV2 in the memory cell is at the LOW level.

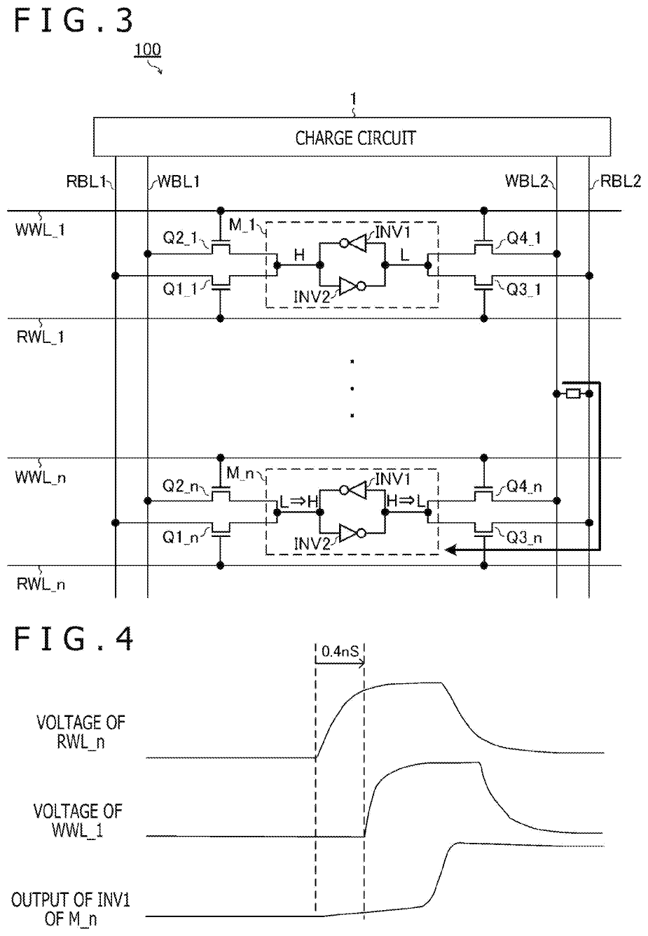

When write operation of writing data “1” to the memory cell M_1 and read operation of reading out the data “0” from the memory cell M_n are simultaneously executed in the state illustrated in FIG. 2, the data written in the memory cell M_n is inverted from “0” to “1” as illustrated in FIG. 3 due to a short-circuit path between the second write bit line WBL2 and the second read bit line RBL2.

If this output failure of the memory cell M_n can be detected, the short-circuit between the write bit line and the read bit line can be detected.

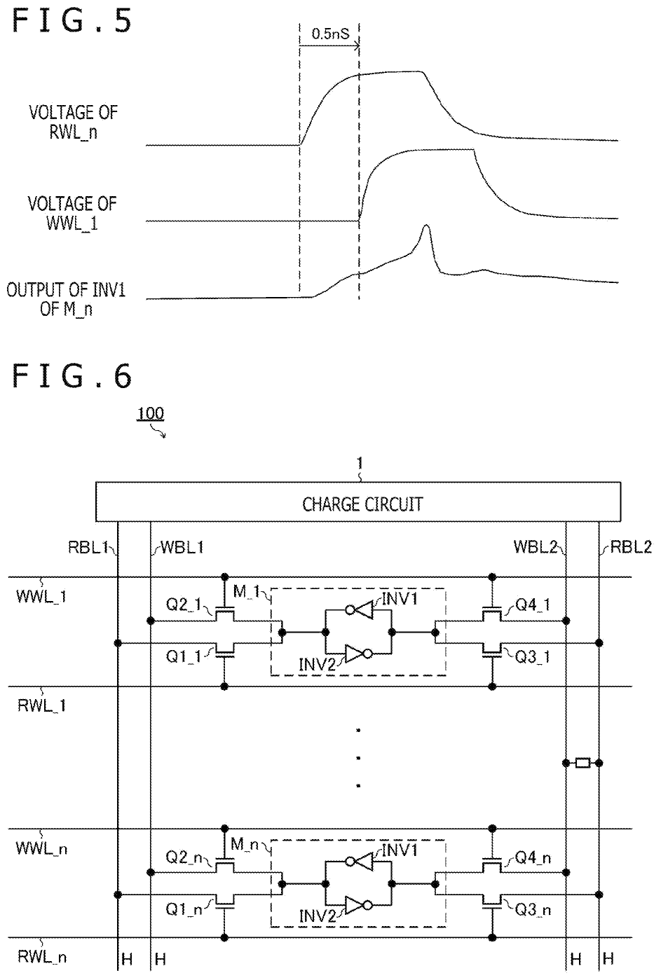

When the deviation between the write operation of writing the data “1” to the memory cell M_1 and the read operation of reading out the data “0” from the memory cell M_n is 0.4 nS as in a timing chart of FIG. 4, the data written in the memory cell M_n is inverted from “0” to “1” as illustrated in FIG. 3. However, when the deviation between the write operation of writing the data “1” to the memory cell M_1 and the read operation of reading out the data “0” from the memory cell M_n becomes 0.5 nS as in a timing chart of FIG. 5, it is impossible to reproduce the inversion of the data written in the memory cell M_n.

That is, the output failure ceases to occur when the write operation and the read operation slightly deviate. Therefore, there is a possibility of omission of detection when the short-circuit between the write bit line and the read bit line is detected with reliance on the output failure.

Further, in the 2-port RAM 100 according to the comparative example, at the time of standby in which a clock input for starting write operation or read operation is awaited, as illustrated in FIG. 6, the charge circuit 1 charges the first read bit line RBL1, the first write bit line WBL1, the second read bit line RBL2, and the second write bit line WBL2.

There is no technique for detecting the short-circuit between the write bit line and the read bit line at the time of standby of the 2-port RAM 100 according to the comparative example.

In view of the above consideration, a novel embodiment that can suppress omission of detection of the short-circuit between the write bit line and the read bit line will be proposed below.

### 2-Port RAM (First Embodiment)

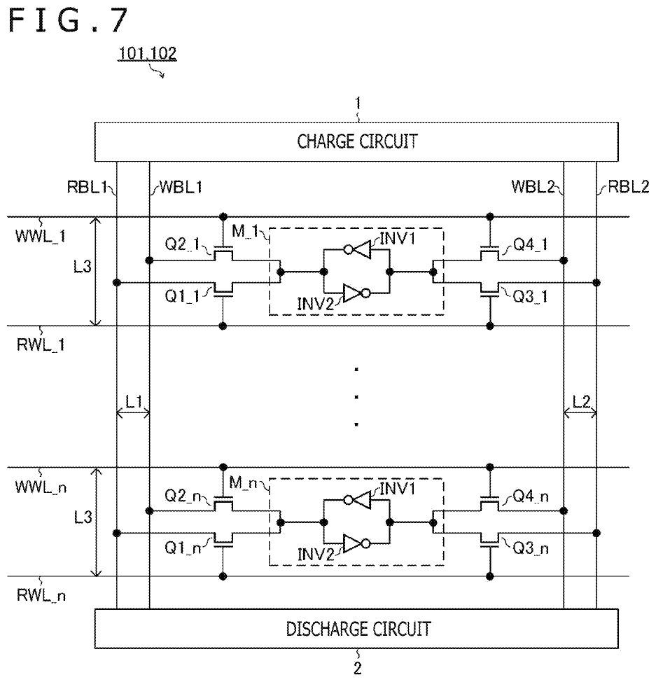

FIG. 7 is a schematic diagram illustrating the major part of a 2-port RAM according to a first embodiment. In FIG. 7, the same part as that in FIG. 1 is given the same numeral, and detailed description thereof is omitted.

A 2-port RAM 101 according to the first embodiment has a first read bit line RBL1, a first write bit line WBL1, a second read bit line RBL2, and a second write bit line WBL2.

The 2-port RAM 101 according to the first embodiment includes n memory cells M_1 to M_n, n read word lines RWL_1 to RWL_n, n write word lines WWL_1 to WWL_n, n first switches Q1_1 to Q1_n, n second switches Q2_1 to Q2_n, n third switches Q3_1 to Q3_n, n fourth switches Q4_1 to Q4_n, a charge circuit 1, and a discharge circuit 2.

A distance L1 between the first read bit line RBL1 and the first write bit line WBL1 and a distance L2 between the second read bit line RBL2 and the second write bit line WBL2 are each shorter than a distance L3 between the read word line RWL_k (k is a natural number that is at least 1 and at most n) and the write word line WWL_k. In this configuration, a short-circuit between the write bit line and the read bit line is liable to occur, and therefore, it is required to surely detect the short-circuit.

The charge circuit 1 is configured to charge one of the first and second read bit lines RBL1 and RBL2 and the first and second write bit lines WBL1 and WBL2 at the time of short-circuit detection (when a short-circuit between the write bit line and the read bit line is detected). More specifically, in the present embodiment, the charge circuit 1 is configured to charge the first and second read bit lines RBL1 and RBL2 at the time of standby.

The discharge circuit 2 is configured to discharge the other of the first and second read bit lines RBL1 and RBL2 and the first and second write bit lines WBL1 and WBL2 at the time of short-circuit detection. More specifically, in the present embodiment, the discharge circuit 2 is configured to discharge the first and second write bit lines WBL1 and WBL2 at the time of standby.

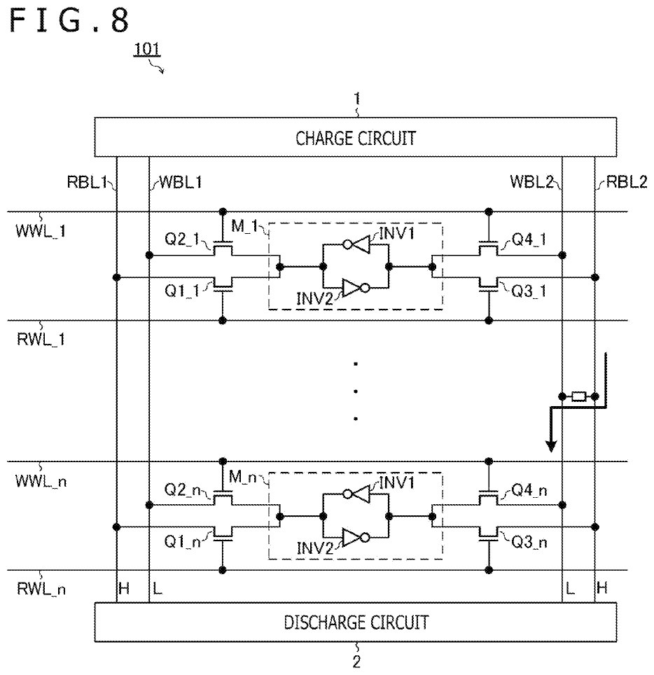

FIG. 8 is a schematic diagram illustrating the major part of the 2-port RAM according to the first embodiment at the time of standby in a case in which there is a short-circuit between the second write bit line WBL2 and the second read bit line RBL2. As illustrated in FIG. 8, a voltage of the second write bit line WBL2 is at the LOW level due to discharge by the discharge circuit 2, and a voltage of the second read bit line RBL2 is at the HIGH level due to charge by the charge circuit 1. Thus, a current flows in the short-circuit path between the second write bit line WBL2 and the second read bit line RBL2. As a result, when there is the short-circuit between the write bit line and the read bit line, the current consumption of the 2-port RAM 101 according to the first embodiment at the time of standby becomes high compared with a case in which there is no short-circuit between the write bit line and the read bit line.

The short-circuit between the write bit line and the read bit line can be detected by current consumption measurement of the 2-port RAM 101 according to the first embodiment at the time of standby. Thus, the short-circuit between the write bit line and the read bit line can be detected without executing adjustment to cause write operation and read operation to occur almost precisely simultaneously. Therefore, the 2-port RAM 101 according to the first embodiment can suppress omission of detection of the short-circuit between the write bit line and the read bit line.

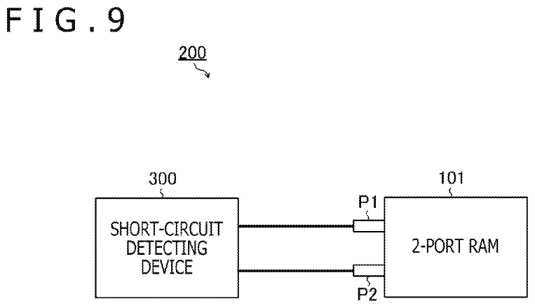

For example, a short-circuit detection system 200 illustrated in FIG. 9 may be constructed in pre-shipment inspection of the 2-port RAM 101 according to the first embodiment. The short-circuit detection system 200 includes the 2-port RAM 101 according to the first embodiment and a short-circuit detecting device 300. The short-circuit detecting device 300 is connected to a supply voltage application pin P1 and a ground voltage application pin P2 of the 2-port RAM 101 according to the first embodiment. The short-circuit detecting device 300 applies a supply voltage to the supply voltage application pin P1 of the 2-port RAM 101 according to the first embodiment and applies a ground potential to the ground voltage application pin P2 of the 2-port RAM 101 according to the first embodiment. The short-circuit detecting device 300 measures the current consumption of the 2-port RAM 101 according to the first embodiment at the time of standby and detects a short-circuit between the write bit line and the read bit line on the basis of the measured current consumption. Specifically, the short-circuit detecting device 300 detects a short-circuit between the write bit line and the read bit line when the measured current consumption is higher than a threshold, but does not detect a short-circuit between the write bit line and the read bit line when the measured current consumption is equal to or lower than the threshold.

At the time of standby, the first switches Q1_1 to Q1_n, the second switches Q2_1 to Q2_n, the third switches Q3_1 to Q3_n, and the fourth switches Q4_1 to Q4_n are in the off-state. This can prevent inversion of data written in a memory cell caused by flowing of a current in a short-circuit path between the write bit line and the read bit line at the time of standby.

Moreover, in the 2-port RAM 101 according to the first embodiment, the first and second read bit lines RBL1 and RBL2 are charged at the time of standby, and therefore, it becomes easy to read data from a memory cell when a transition is made from standby to read operation.

### 2-Port RAM (Second Embodiment)

A schematic diagram illustrating the major part of a 2-port RAM 102 according to a second embodiment is the same as the schematic diagram illustrating the major part of the 2-port RAM 101 according to the first embodiment (see FIG. 7).

The 2-port RAM 102 according to the second embodiment has a test mode.

The charge circuit 1 is configured to charge one of the first and second read bit lines RBL1 and RBL2 and the first and second write bit lines WBL1 and WBL2 at the time of short-circuit detection (when a short-circuit between the write bit line and the read bit line is detected). More specifically, in the present embodiment, the charge circuit 1 is configured to charge the first and second write bit lines WBL1 and WBL2 at the time of the test mode.

The discharge circuit 2 is configured to discharge the other of the first and second read bit lines RBL1 and RBL2 and the first and second write bit lines WBL1 and WBL2 at the time of short-circuit detection. More specifically, in the present embodiment, the discharge circuit 2 is configured to discharge the first and second read bit lines RBL1 and RBL2 at the time of the test mode.

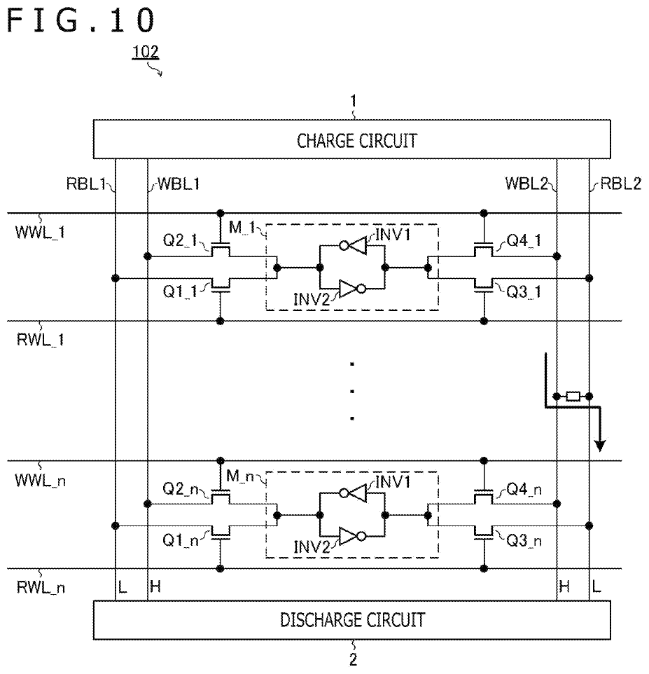

FIG. 10 is a schematic diagram illustrating the major part of the 2-port RAM according to the second embodiment at the time of the test mode in a case in which there is a short-circuit between the second write bit line WBL2 and the second read bit line RBL2. As illustrated in FIG. 10, the voltage of the second write bit line WBL2 is at the HIGH level due to charge by the charge circuit 1, and the voltage of the second read bit line RBL2 is at the LOW level due to discharge by the discharge circuit 2. Thus, a current flows in the short-circuit path between the second write bit line WBL2 and the second read bit line RBL2. As a result, when there is the short-circuit between the write bit line and the read bit line, the current consumption of the 2-port RAM 102 according to the second embodiment at the time of the test mode becomes high compared with a case in which there is no short-circuit between the write bit line and the read bit line.

The test mode is set separately from the time of standby. Therefore, even when the first and second read bit lines RBL1 and RBL2 are discharged in the test mode as in the present embodiment, a trouble that it becomes difficult to read out data from a memory cell when a transition is made from standby to read operation does not occur.

In the present embodiment, both the first and second read bit lines RBL1 and RBL2 and the first and second write bit lines WBL1 and WBL2 may be charged by the charge circuit 1 at the time of standby, for example. This makes it easy to read out data from a memory cell when a transition is made from standby to read operation.

As a modification example of the present embodiment, the charge circuit 1 may be configured to charge the first and second read bit lines RBL1 and RBL2 at the time of the test mode, and the discharge circuit 2 may be configured to discharge the first and second write bit lines WBL1 and WBL2 at the time of the test mode.

### <Others>

For configurations of the technology, besides the above-described embodiments, various changes can be added without departing from the gist of the technology. It should be recognized that the above-described embodiments are exemplification in all points and are not restrictive, and it should be understood that the technical range of the present technology is indicated by not the explanation of the above-described embodiments but the scope of claims and all changes that belong to meanings and the range equivalent to the scope of claims are included therein.

For example, the RAMs according to the above-described respective embodiments are 2-port RAMs having a port exclusively for input and a port exclusively for output. However, instead of the 2-port RAMs, dual-port RAMs having a first input-output port and a second input-output port independent of each other may be used.

The RAM (101, 102) described above has a configuration (first configuration) in which the RAM includes a first read bit line (RBL1), a first write bit line (WBL1), a second read bit line (RBL2), a second write bit line (WBL2), a charge circuit (1) configured to charge one of the first and second read bit lines and the first and second write bit lines at a time of short-circuit detection, and a discharge circuit (2) configured to discharge the other of the first and second read bit lines and the first and second write bit lines at the time of the short-circuit detection.

The RAM with the above-described first configuration can suppress omission of detection of the short-circuit between the write bit line and the read bit line.

According to the RAM with the above-described first configuration, the RAM may have a configuration (second configuration) in which the RAM further includes memory cells (M_1 to M_n), first switches (Q1_1 to Q1_n) disposed between corresponding ones of the memory cells and the first read bit line, second switches (Q2_1 to Q2_n) disposed between corresponding ones of the memory cells and the first write bit line, third switches (Q3_1 to Q3_n) disposed between corresponding ones of the memory cells and the second read bit line, and fourth switches (Q4_1 to Q4_n) disposed between corresponding ones of the memory cells and the second write bit line, the first to fourth switches being in an off-state at the time of the short-circuit detection.

The RAM with the above-described second configuration can prevent inversion of data written in a memory cell caused by flowing of a current in a short-circuit path between the write bit line and the read bit line at the time of short-circuit detection.

According to the RAM with the above-described first or second configuration, the RAM may have a configuration (third configuration) in which the time of the short-circuit detection is a time of standby, the charge circuit is configured to charge the first and second read bit lines at the time of the short-circuit detection, and the discharge circuit is configured to discharge the first and second write bit lines at the time of the short-circuit detection.

In the RAM with the above-described third configuration, the first and second read bit lines are charged at the time of standby. Therefore, it becomes easy to read out data from a memory cell when a transition is made from standby to read operation.

According to the RAM with any one of the above-described first to third configurations, the RAM may have a configuration (fourth configuration) in which the RAM further includes read word lines and write word lines, a distance between the first read bit line and the first write bit line and a distance between the second read bit line and the second write bit line being each shorter than a distance between a corresponding one of the read word lines and a corresponding one of the write word lines.

In the RAM with the above-described fourth configuration, a short-circuit between the write bit line and the read bit line is liable to occur. Therefore, the suppression of omission of detection of the short-circuit between the write bit line and the read bit line becomes more effective.

The short-circuit detection system (200) described above has a configuration (fifth configuration) in which the short-circuit detection system includes the RAM with any one of the above-described first to third configurations and a short-circuit detecting device (300) configured to execute the short-circuit detection on the basis of current consumption of the RAM.

In the short-circuit detection system with the above-described fifth configuration, omission of detection of the short-circuit between the write bit line of the RAM and the read bit line of the RAM can be suppressed.

According to the RAM and the short-circuit detection system disclosed in the present specification, omission of detection of the short-circuit between the write bit line and the read bit line can be suppressed.

What is claimed is:

1. A random access memory comprising:
a first read bit line;
a first write bit line;
a second read bit line;
a second write bit line;
a charge circuit configured to charge one of the first and second read bit lines and the first and second write bit lines at a time of short-circuit detection; and
a discharge circuit configured to discharge the other of the first and second read bit lines and the first and second write bit lines at the time of the short-circuit detection.

2. The random access memory according to claim 1, further comprising:
memory cells;
first switches disposed between corresponding ones of the memory cells and the first read bit line;
second switches disposed between corresponding ones of the memory cells and the first write bit line;
third switches disposed between corresponding ones of the memory cells and the second read bit line; and
fourth switches disposed between corresponding ones of the memory cells and the second write bit line, wherein
the first to fourth switches are in an off-state at the time of the short-circuit detection.

3. The random access memory according to claim 1, wherein
the time of the short-circuit detection is a time of standby,
the charge circuit is configured to charge the first and second read bit lines at the time of the short-circuit detection, and
the discharge circuit is configured to discharge the first and second write bit lines at the time of the short-circuit detection.

4. The random access memory according to claim 1, further comprising:
read word lines; and
write word lines,
wherein a distance between the first read bit line and the first write bit line and a distance between the second read bit line and the second write bit line are each shorter than a distance between a corresponding one of the read word lines and a corresponding one of the write word lines.

5. A short-circuit detection system comprising:
the random access memory according to claim 1; and
a short-circuit detecting device configured to execute the short-circuit detection on a basis of current consumption of the random access memory.
